(19) United States
(12) Patent Application Publication
(10) Pub. No.: US 2026/0038774 A1
(43) Pub. Date: Feb. 5, 2026

(54) PLASMA-RESISTANT COMPOSITE LAMINATE

(71) Applicant: HUNG JIE TECHNOLOGY CORPORATION, Hsinchu County (TW)

(72) Inventors: Shao-Wei LU, Hsinchu County (TW); Cheng-Lin KUO, Hsinchu County (TW); Chia-Yang WU, Hsinchu County (TW); Ting-Chun WANG, Hsinchu County (TW)

(73) Assignee: HUNG JIE TECHNOLOGY CORPORATION, Hsinchu County (TW)

(21) Appl. No.: 19/230,515

(22) Filed: Jun. 6, 2025

(30) Foreign Application Priority Data
Jul. 30, 2024 (TW) 113128319

(51) Int. Cl. H01J 37/32

(52) U.S. Cl. CPC H01J 37/32495

(57) ABSTRACT

The present invention provides a plasma-resistant composite laminate comprising a substrate, a first adhesion layer and a first plasma-resistant layer. The substrate has an upper surface, and the first adhesion layer is disposed between the upper surface of the substrate and the first plasma-resistant layer. An arithmetic average roughness (Ra) of the upper surface of the substrate is from 2 μm to 10 μm, a porosity of the first adhesion layer is from 0.05% to 10%, a porosity of the first plasma-resistant layer is from 0.03% to 6%, and a ratio of the porosity of the first adhesion layer relative to the porosity of the first plasma-resistant layer ranges from 1.6 to 333.33. The plasma-resistant composite laminate described has good performance on adhesion, thereby reducing the incidence of peeling during plasma treatment, and thus prolonging the lifetime of plasma reaction chamber.

### CROSS-REFERENCE TO RELATED APPLICATION

Pursuant to 35 U.S.C. § 119(a), this application claims the benefit of the priority to Taiwan Patent Application No. 113128319 filed Jul. 30, 2024. The content of the prior application is incorporated herein by its entirety.

### BACKGROUND OF THE INVENTION

### 1. Field of the Invention

The present invention relates to a composite laminate, especially for a plasma bombardment-resistant and corrosion-resistant composite laminate.

### 2. Description of the Prior Arts

Plasma treatment is a common and important technology in the preparation of miniature semiconductor devices. Typically, a material is placed in a plasma reaction chamber for exciting a specific gas to a plasma state before treating the material with plasma. However, in addition to the material to be treated, the plasma state gas will bombard and damage the inner wall or the components (such as the gas distribution component, the substrate support component and the gas exhaust component, etc.) of the plasma reaction chamber in the same time. If the plasma reaction chamber contains halogen gas, such as fluorine or chlorine, the halogen gases would be easily decomposed by the plasma state gas into chemically active free radicals, which corrode the inner wall or the components of the plasma reaction chamber.

To solve the challenges in the foresaid plasma treatment, a wear- and corrosion-resistant coating is applied to the interior of the chamber, including the inner wall and the components, to protect it from damage and corrosion caused by the plasma state gas, thereby maintaining the normal performance of the plasma reaction chamber and its prolonged lifetime. In addition, it is well-known that yttrium oxides, yttrium fluorides or aluminum oxides exhibit good resistance to plasma corrosion, and therefore, plasma-resistant coating layers can be made from these materials by methods such as atmospheric plasma spray (APS), suspension plasma spray (SPS), physical vapor deposition (PVD) or atomic layer deposition (ALD).

Nevertheless, the single layer plasma-resistant coating formed from the foresaid materials typically exhibits poor adhesion to the inner wall or the components of the plasma reaction chamber, resulting in easy peeling of the plasma-resistant coating under continuous plasma state gas bombardment, resulting in that the plasma reaction chamber interior cannot be continuously and fully protected. Therefore, further development and research on the plasma-resistant coating are still needed, with the aim of improving its adhesion ability to prevent the problems of easy peeling and detachment and to prolong the lifetime of the plasma reaction chamber.

### SUMMARY OF THE INVENTION

In view of the problems in the prior art, the objective of the present invention is to provide a plasma-resistant composite laminate, which can exhibit better adhesion ability than the conventional plasma-resistant coating. Thus, the plasma-resistant composite laminate can be applied to the interior of the plasma reaction chamber, thereby efficiently solving the problems of easy peeling and prolonging the lifetime of the plasma reaction chamber.

To achieve the objective above, the present invention provides the plasma-resistant composite laminate, comprising a substrate, a first adhesion layer and a first plasma-resistant layer. The substrate has an upper surface, and the first adhesion layer is disposed between the upper surface of the substrate and the first plasma-resistant layer. The upper surface has an arithmetic average roughness (Ra) ranging from 2 micrometers (μm) to 10 μm. The first adhesion layer has a porosity of 0.05% to 10%, the first plasma-resistant layer has a porosity of 0.03% to 6%, and a ratio of the porosity of the first adhesion layer relative to the porosity of the first plasma-resistant layer ranges from 1.6 to 333.33.

By disposing the first adhesion layer between the substrate and the first plasma-resistant layer, and controlling the roughness of the upper surface of the substrate, the porosities of the first adhesion layer and the first plasma-resistant layer, and their ratio within a specific range simultaneously, the plasma-resistant composite laminate exhibits good adhesion (for example, greater than 6000 kN/mm²), so that it is effective to resist the plasma corrosion (that is, the bombardment of plasma state gas) and is not prone to peeling during the process. That is to say, the plasma-resistant composite laminate can continuously provide complete protection to the interior of the plasma reaction chamber to prolong its lifetime.

In some of the embodiments, the ratio of the porosity of the first adhesion layer relative to the first plasma-resistant layer may be from 10 to 333.33, but is not limited thereto. In other embodiments, the ratio of the porosity of the first adhesion layer relative to the first plasma-resistant layer may be from 25 to 333.33. In still other embodiments, the ratio of the porosity of the first adhesion layer relative to the first plasma-resistant layer may be from 50 to 333.33. In yet other embodiments, the ratio of the porosity of the first adhesion layer relative to the first plasma-resistant layer may be from 80 to 333.33.

In some of the embodiments, the material of the first adhesion layer may contain yttrium oxide (Y₂O₃), yttrium fluoride (YF₃), yttrium oxyfluoride (YOF), aluminium oxide (Al₂O₃), yttrium aluminum oxide (Y₃Al₅O₁₂) or any combinations thereof. In other embodiments, the material of the first adhesion layer may contain yttrium oxide, yttrium aluminum oxide or any combinations thereof.

In some of the embodiments, a thickness of the first adhesion layer may be from 2 μm to 200 μm, but is not limited thereto. In other embodiments, the thickness of the first adhesion layer may be from 2 μm to 150 μm. In still other embodiments, the thickness of the first adhesion layer may be from 2 μm to 100 μm. In yet other embodiments, the thickness of the first adhesion layer may be from 10 μm to 100 μm.

In some of the embodiments, the Ra of a surface of the first adhesion layer may be from 2 μm to 10 μm. In particular, the surface of the first adhesion layer refers to a surface opposite the substrate.

In some of the embodiments, the plasma-resistant composite laminate may also contain a second adhesion layer, which is disposed between the first adhesion layer and the upper surface of the substrate. The porosity of the second adhesion layer may be from 0.05% to 10%, which differs from the porosity of the first adhesion layer. In other embodiments, the porosity of the first adhesion layer is larger than the porosity of the second adhesion layer.

In some of the embodiments, the ratio of the porosity of the second adhesion layer relative to the first plasma-resistant layer may be from 1.6 to 333.33, but is not limited thereto. In other embodiments, the ratio of the porosity of the second adhesion layer relative to the first plasma-resistant layer may be from 10 to 333.33. In still other embodiments, the ratio of the porosity of the second adhesion layer relative to the first plasma-resistant layer may be from 25 to 333.33. In yet other embodiments, the ratio of the porosity of the second adhesion layer relative to the first plasma-resistant layer may be from 50 to 333.33. In still another embodiment, the ratio of the porosity of the second adhesion layer relative to the first plasma-resistant layer may be from 80 to 333.33.

In some of the embodiments, the material of the second adhesion layer may contain yttrium oxide, yttrium fluoride, yttrium oxyfluoride, aluminium oxide, yttrium aluminum oxide or any combinations thereof. In other embodiments, the material of the second adhesion layer may also contain yttrium oxide, yttrium aluminum oxide or any combinations thereof.

In some of the embodiments, the thickness of the second adhesion layer may be from 2 μm to 200 μm, but is not limited thereto. In other embodiments, the thickness of the second adhesion layer may be from 2 μm to 150 μm. In still other embodiments, the thickness of the second adhesion layer may be from 2 μm to 100 μm. In yet other embodiments, the thickness of the second adhesion layer may be from 2 μm to 80 μm. In still another embodiment, the thickness of the second adhesion layer may be from 2 μm to 45 μm.

In some embodiments, the Ra of the surface of the second adhesion layer may be from 2 μm to 10 μm, but is not limited thereto. In particular, the surface of the second adhesion layer refers to a surface opposite the substrate.

In some of the embodiments, multiple adhesion layers, such as a third adhesion layer and a fourth adhesion layer, may be disposed between the second adhesion layer and the upper surface. The range of the porosity, the material, the ranges of the thickness and the Ra of the surface of the multiple adhesion layers may be the same as those of the second adhesion layer. However, these adhesion layers differ from each other and the second adhesion layer in at least one of the porosity, the material, the thickness and the Ra of the surface, meaning that these adhesion layers themselves and the second adhesion layer are distinct independent layers.

In some of the embodiments, the porosity of the first plasma-resistant layer may be from 0.03% to 3%, but is not limited thereto. In other embodiments, the porosity of the first plasma-resistant layer may be from 0.03% to 2%. In still other embodiments, the porosity of the first plasma-resistant layer may be from 0.03% to 1%.

In some of the embodiments, the material of the first plasma-resistant layer contains yttrium oxide, yttrium fluoride, yttrium oxyfluoride, aluminium oxide, yttrium aluminum oxide or any combinations thereof. In other embodiments, the material of the first plasma-resistant layer may also contain yttrium oxide, yttrium aluminum oxide or any combinations thereof.

In some of the embodiments, the thickness of the first plasma-resistant layer may be from 15 μm to 300 μm, but is not limited thereto. In other embodiments, the thickness of the first plasma-resistant layer may be from 50 μm to 300 μm. In still other embodiments, the thickness of the first plasma-resistant layer may be from 50 μm to 200 μm. In yet other embodiments, the thickness of the first plasma-resistant layer may be from 50 μm to 150 μm.

In some of the embodiments, the Ra of the surface of the first plasma-resistant layer may be from 1 μm to 10 μm, but is not limited thereto. In other embodiments, the Ra of the surface of the first plasma-resistant layer may be from 2 μm to 10 μm. In particular, the surface of the first plasma-resistant layer refers to a surface opposite the substrate.

According to the present invention, multiple plasma-resistant layers, such as a second plasma-resistant layer and a third plasma-resistant layer, may be disposed on the surface of the first plasma-resistant layer. The range of the porosity, material, the ranges of the thickness and the Ra of the surface of the multiple plasma-resistant layers may be the same as those of the first plasma-resistant layer. However, these plasma-resistant layers differ from each other and the first plasma-resistant layer in at least one of the porosity, the material, the thickness and the Ra of the surface, meaning that these plasma-resistant layers themselves and the first plasma-resistant layer are distinct independent layers.

According to the present invention, the material of the substrate has no particular limitations. Under the premise of not affecting the achieved effects of the present application, a person skilled in the art can select the material of the substrate as needed. For example, the material of the substrate may be chosen from aluminum alloy, stainless steel, quartz or aluminium oxide, but is not limited thereto.

In some of the embodiments, the thickness of the substrate may be from 2 millimeters (mm) to 50 mm, but is not limited thereto.

In some of the embodiments, the Ra of the upper surface of the substrate may be from 1 μm to 10 μm, but is not limited thereto.

In the present specification, the Ra of the surface is analyzed by a surface roughness measuring instrument according to ISO1997 standard method.

In the present specification, a range expressed as “a small value to a large value,” unless specifically stated otherwise, indicates a range that is greater than or equal to the small value and less than or equal to the large value. For example, the Ra ranging from 2 μm to 10 μm indicates that it is “larger than or equal to 2 μm and less than or equal to 10 μm”.

### BRIEF DESCRIPTION OF THE DRAWINGS

FIG. 1 is a schematic longitudinal cross-sectional view showing the plasma-resistant composite laminate of the example 1.

FIG. 2 is a schematic longitudinal cross-sectional view showing the plasma-resistant composite laminate of the example 5.

### DETAILED DESCRIPTION OF THE PREFERRED EMBODIMENTS

Hereinafter, the implementation of the plasma-resistant composite laminate and comparative examples are described below. A person skilled in the art can easily realize the advantages and effects of the present invention from the following examples and comparative examples. Various modifications and variations can be made in order to practice or apply the present invention without departing from the spirit of the present application.

### Example 1: Plasma-Resistant Composite Laminate

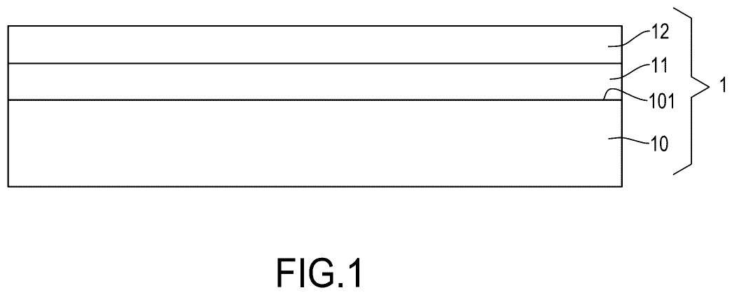

FIG. 1 is the schematic longitudinal cross-sectional view showing the plasma-resistant composite laminate of Example 1. In particular, the plasma-resistant composite laminate 1 of Example 1 comprises a substrate 10, a first adhesion layer 11 and a first plasma-resistant layer 12. In addition, the first adhesion layer 11 is formed on an upper surface 101 of the substrate 10, and the first plasma-resistant layer 12 is formed on a surface of the first adhesion layer 11.

The plasma-resistant composite laminate 1 in Example 1 is mainly prepared by the method as described below. First, the substrate 10 made of stainless steel was provided, and the upper surface 101 of the substrate 10 was treated by a cyclone sandblasting machine so that its Ra was about 4.5 μm. Next, yttrium aluminum oxide was chosen as the material, and the first adhesion layer 11 with the thickness of about 50 μm was formed on the upper surface 101 of the substrate 10 by atmospheric plasma spraying under a high-power condition of 46 kW to 48 kW. The first adhesion layer 11 had a porosity of about 0.05% and an Ra of the surface of about 4.5 μm. Then, yttrium aluminum oxide was chosen as the material, and the first plasma-resistant layer 12 was formed on the surface of the first adhesion layer 11 by atmospheric plasma spraying under a high-power condition of about larger than 48 kW. The first plasma-resistant layer 12 had a porosity of about 0.03%, a thickness of about 100 μm, and an Ra of the surface of about 4.3 μm. In addition, the ratio of the porosity of the first adhesion layer 11 relative to that of the first plasma-resistant layer 12 was about 1.67. Finally, the surface of the first plasma-resistant layer 12 was sequentially cleaned with carbon dioxide and high-pressure water, and the plasma-resistant composite laminate 1 in Example 1 was obtained after drying in an oven.

### Examples 2 to 4: Plasma-Resistant Composite Laminate

The plasma-resistant composite laminates in Examples 2 to 4 possess the same structure as the plasma-resistant composite laminate in Example 1, and their preparation process is similar to that of the plasma-resistant composite laminate in Example 1. The major differences are described as below. In Example 2, yttrium aluminum oxide was formed on the upper surface of the substrate by atmospheric plasma spraying under a medium-power condition of 42 kW to 44 kW to obtain the first adhesion layer with the thickness of about 50 μm, the porosity of about 2.5% and the Ra of the surface of about 4.4 μm, and the ratio of the porosity of the first adhesion layer relative to that of the first plasma-resistant layer was about 84. In Example 3, yttrium aluminum oxide was formed on the upper surface of the substrate by atmospheric plasma spraying under a low-power condition of larger than or equal to 40 kW and lower than 42 kW to obtain the first adhesion layer with the thickness of about 50 μm, the porosity of about 5% and the Ra of the surface of about 5 μm, and the ratio of the porosity of the first adhesion layer relative to that of the first plasma-resistant layer was about 167. In Example 4, yttrium aluminum oxide was formed on the upper surface of the substrate by atmospheric plasma spraying under an extremely low-power condition of lower than 40 kW to obtain the first adhesion layer with the thickness of about 50 μm, the porosity of about 10% and the Ra of the surface of about 6.2 μm, and the ratio of the porosity of the first adhesion layer relative to that of the first plasma-resistant layer was about 333.33. Apart from the foresaid differences in the first adhesion layer, Examples 2 to 4 are prepared according to the same preparation process as Example 1 to make the plasma-resistant composite laminates in Examples 2 to 4.

### Example 5: Plasma-Resistant Composite Laminate

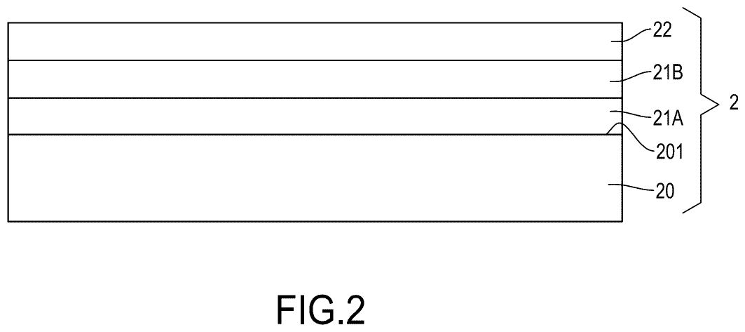

FIG. 2 is the schematic longitudinal cross-sectional view showing the plasma-resistant composite laminate of Example 5. In particular, the plasma-resistant composite laminate 2 of Example 5 comprises a substrate 20, a second adhesion layer 21A, a first adhesion layer 21B and a first plasma-resistant layer 22. In addition, the second adhesion layer 21A is formed on an upper surface 201 of the substrate 20, the first adhesion layer 21B is formed on a surface of second adhesion layer 21A, and the first plasma-resistant layer 22 is formed on a surface of the first adhesion layer 21B.

The plasma-resistant composite laminate 2 in Example 5 is mainly prepared by the method as described below. First, the substrate 20 made of stainless steel was provided, and the upper surface 201 of the substrate 20 was treated by the cyclone sandblasting machine so that its Ra was about 4.5 μm. Next, yttrium oxide was chosen as the material, and the second adhesion layer 21A with the thickness of about 20 μm was formed on the upper surface 201 of the substrate 20 by atmospheric plasma spraying under a medium-power condition of 42 kW to 44 kW. The second adhesion layer 21A had a porosity of about 0.5%, and an Ra of the surface of about 4.5 μm. Later on, yttrium aluminum oxide was chosen as the material, and the first adhesion layer 21B was formed on the surface of the second adhesion layer 21A by atmospheric plasma spraying under an extremely low-power condition of lower than 40 kW. The first adhesion layer 21B had a porosity of about 10%, a thickness of about 70 μm, and an Ra of the surface of about 7.5 μm. Afterwards, yttrium aluminum oxide was chosen as the material, and the first plasma-resistant layer 22 was formed on the surface of the first adhesion layer 21B by atmospheric plasma spraying under a high-power condition of larger than 48 kW. The first plasma-resistant layer 22 had a porosity of about 0.03%, a thickness of about 70 μm, and an Ra of the surface of about 4.3 μm. In addition, the ratio of the porosity of the first adhesion layer 21B relative to that of the first plasma-resistant layer 22 was about 333.33. Finally, the surface of the first plasma-resistant layer 22 was sequentially cleaned with carbon dioxide and high-pressure water, and the plasma-resistant composite laminate 2 in Example 5 was obtained after drying in the oven.

### Comparative Example 1: Single Layer Plasma-Resistant Coating

Comparative example 1 represents a plasma-resistant coating of the prior arts, and Comparative example 1 is mainly prepared by the method as described below. First, a substrate made of stainless steel was provided, and the upper surface of the substrate was treated by the cyclone sandblasting machine, so that its Ra was about 4.5 μm. Next, yttrium aluminum oxide was chosen as the material, and an yttrium aluminum oxide layer was formed on the upper surface of the substrate by atmospheric plasma spraying under a high-power condition of larger than 48 kW. Finally, the yttrium aluminum oxide layer was sequentially cleaned with carbon dioxide and high-pressure water, and the single layer plasma-resistant coating in Comparative example 1 was obtained after drying in the oven. The yttrium aluminum oxide layer had a porosity of about 0.03%, a thickness of about 150 μm, and an Ra of the surface of about 4.3 μm.

### Test Example 1: Determination of Porosity

In Test example 1, the plasma-resistant composite laminates of Examples 1 to 5 were used as samples to be tested. In particular, the images of the plasma-resistant composite laminates in Examples 1 to 5 were obtained by the scanning electron microscope (SEM) and then imported into ImageJ software for analysis. A region to be calculated was selected, and the ratio of the pore area relative to the total material area was calculated by the software to be determined as the porosity. The porosity of each laminate in Examples 1 to 5 is determined by using the method mentioned above, and the results are shown in Table 1 below. Furthermore, the ratio of the porosity of the first adhesion layer relative to that of the first plasma-resistant layer of each laminate in Examples 1 to 5 are also calculated and the results are shown in Table 1 below.

Table 1. The porosity of each layer and the ratio of the porosity of the first adhesion layer relative to that of the first plasma-resistant layer of each laminate in Examples 1 to 5.

| | | | | The ratio of the |
|---|---|---|---|---|
| | Porosity (%) | | | porosity of the first |
| | | | First | adhesion layer |
| | Second | First | plasma- | relative to that of |
| | adhesion | adhesion | resistant | the first plasma- |
| Sample No. | layer | layer | layer | resistant layer |
| Example 1 | — | 0.05 | 0.03 | 1.67 |
| Example 2 | — | 2.5 | 0.03 | 84 |
| Example 3 | — | 5 | 0.03 | 167 |
| Example 4 | — | 10 | 0.03 | 333.33 |
| Example 5 | 0.5 | 10 | 0.03 | 333.33 |

The results in Table 1 above show that, in the plasma-resistant composite laminates of Examples 1 to 5, the porosity of the first adhesion layer was greater than that of the first plasma-resistant layer, and the ratio of the porosity of the first adhesion layer relative to that of the first plasma-resistant layer fall within a specific range from 1.67 to about 333.33.

### Test Example 2: Determination of Adhesion

The adhesion of the plasma-resistant composite laminates of Examples 1 to 5 and the single plasma-resistant coating of Comparative example 1 were determined according to the steps and conditions as described in the standard test method for adhesion or cohesion strength of thermal spray coatings, ASTM C633-13 (2021), and the results are shown in Table 2 below. It is generally considered that the adhesion of the plasma-resistant coating in the plasma reaction chamber should be greater than 6000 kN/mm² to effectively avoid the problems of peeling and thus prolong the lifetime of the plasma reaction chamber. The determination of adhesion was performed for four times for each group, and the results shown in Table 2 represent the average values of four testing results.

Table 2. The results of the adhesion of the plasma-resistant composite laminates in Examples 1 to 5 and the single layer plasma-resistant coating in Comparative Example 1.

| Sample No. | Adhesion (kN/mm²) |
|---|---|
| Example 1 | 6323 |
| Example 2 | 11032 |
| Example 3 | 16872 |
| Example 4 | 17012 |
| Example 5 | 17132 |
| Comparative Example 1 | 4500 |

The results in Table 2 above show that the adhesion of the single layer plasma-resistant coating in Comparative example 1 of 4500 kN/mm² failed to meet the industry-recognized standard, and consequently results in the problems in the prior art of easy peeling from the interior of the plasma reaction chamber including the inner wall and the components. The plasma-resistant composite laminate in Example 1 had the adhesion of 6323 kN/mm² and is significantly greater than the industry-recognized standard. Furthermore, the adhesion in Examples 3 to 5 exhibited more than approximately 2.5 times greater than the industry standard. Therefore, the plasma-resistant composite laminates in Examples 1 to 5 can solve the problems in the prior art of easy peeling caused by adhesion sufficiency.

In view of this, by disposing at least one adhesion layer between the substrate and the plasma-resistant layer, and simultaneously controlling the surface roughness of the substrate, the porosity of the plasma-resistant layer and the adhesion layer, and the ratio between their porosities, the plasma-resistant composite laminate does have good performance of adhesion to meet the industry-recognized standard (for example, greater than 6000 kN/mm²). Therefore, the plasma-resistant composite laminate can resist the plasma corrosion (i.e., bombardment of plasma state gas) and is no more prone to peeling. That is to say, the plasma-resistant composite laminate can continuously provide complete protection to the interior of the plasma reaction chamber and prolong its lifetime.

What is claimed is:

1. A plasma-resistant composite laminate comprising a substrate, a first adhesion layer and a first plasma-resistant layer, the substrate having an upper surface, and the first adhesion layer disposed between the upper surface of the substrate and the first plasma-resistant layer;
wherein, an arithmetic average roughness (Ra) of the upper surface of the substrate is from 2 μm to 10 μm; and a porosity of the first adhesion layer is from 0.05% to 10%, a porosity of the first plasma-resistant layer is from 0.03% to 6%, and a ratio of the porosity of the first adhesion layer relative to the porosity of the first plasma-resistant layer ranges from 1.6 to 333.33.

2. The plasma-resistant composite laminate as claimed in claim 1, wherein a material of the first adhesion layer comprises yttrium oxide, yttrium fluoride, yttrium oxyfluoride, aluminium oxide, yttrium aluminum oxide or any combinations thereof.

3. The plasma-resistant composite laminate as claimed in claim 1, wherein a thickness of the first adhesion layer is from 2 μm to 200 μm.

4. The plasma-resistant composite laminate as claimed in claim 1, wherein an arithmetic average roughness (Ra) of the surface of the first adhesion layer is from 2 μm to 10 μm.

5. The plasma-resistant composite laminate as claimed in claim 1, wherein the plasma-resistant composite laminate comprises a second adhesion layer disposed between the first adhesion layer and the upper surface of the substrate, a porosity of the second adhesion layer is from 0.05% to 10%, and the porosity of the second adhesion layer differs from the porosity of the first adhesion layer.

6. The plasma-resistant composite laminate as claimed in claim 2, wherein the plasma-resistant composite laminate comprises a second adhesion layer disposed between the first adhesion layer and the upper surface of the substrate, a porosity of the second adhesion layer is from 0.05% to 10%, and the porosity of the second adhesion layer differs from the porosity of the first adhesion layer.

7. The plasma-resistant composite laminate as claimed in claim 3, wherein the plasma-resistant composite laminate comprises a second adhesion layer disposed between the first adhesion layer and the upper surface of the substrate, a porosity of the second adhesion layer is from 0.05% to 10%, and the porosity of the second adhesion layer differs from the porosity of the first adhesion layer.

8. The plasma-resistant composite laminate as claimed in claim 4,
wherein the plasma-resistant composite laminate comprises a second adhesion layer disposed between the first adhesion layer and the upper surface of the substrate, a porosity of the second adhesion layer is from 0.05% to 10%, and the porosity of the second adhesion layer differs from the porosity of the first adhesion layer.

9. The plasma-resistant composite laminate as claimed in claim 5, wherein a material of the second adhesion layer comprises yttrium oxide, yttrium fluoride, yttrium oxyfluoride, aluminium oxide, yttrium aluminum oxide or any combinations thereof.

10. The plasma-resistant composite laminate as claimed in claim 6, wherein a material of the second adhesion layer comprises yttrium oxide, yttrium fluoride, yttrium oxyfluoride, aluminium oxide, yttrium aluminum oxide or any combinations thereof.

11. The plasma-resistant composite laminate as claimed in claim 5, wherein a thickness of the second adhesion layer is from 2 μm to 200 μm.

12. The plasma-resistant composite laminate as claimed in claim 6, wherein a thickness of the second adhesion layer is from 2 μm to 200 μm.

13. The plasma-resistant composite laminate as claimed in claim 7, wherein a thickness of the second adhesion layer is from 2 μm to 200 μm.

14. The plasma-resistant composite laminate as claimed in claim 8, wherein a thickness of the second adhesion layer is from 2 μm to 200 μm.

15. The plasma-resistant composite laminate as claimed in claim 1, wherein a material of the first plasma-resistant layer comprises yttrium oxide, yttrium fluoride, yttrium oxyfluoride, aluminium oxide, yttrium aluminum oxide or any combinations thereof.

16. The plasma-resistant composite laminate as claimed in claim 1, wherein a thickness of the first plasma-resistant layer is from 15 μm to 300 μm.

17. The plasma-resistant composite laminate as claimed in claim 2, wherein a thickness of the first plasma-resistant layer is from 15 μm to 300 μm.

18. The plasma-resistant composite laminate as claimed in claim 3, wherein a thickness of the first plasma-resistant layer is from 15 μm to 300 μm.

19. The plasma-resistant composite laminate as claimed in claim 4, wherein a thickness of the first plasma-resistant layer is from 15 μm to 300 μm.

20. The plasma-resistant composite laminate as claimed in claim 1, wherein a material of the substrate comprises aluminum alloy, stainless steel, quartz or aluminium oxide.
